(19) United States
(12) Patent Application Publication
(10) Pub. No.: US 2026/0370160 A1
(43) Pub. Date: Nov. 19, 2026

(54) PIEZOELECTRIC CIRCUIT, PIEZOELECTRIC DEVICE, AND PIEZOELECTRIC GENERATOR

(71) Applicant: Abel Sjodin, Tacoma, WA (US)

(72) Inventor: Abel Sjodin, Tacoma, WA (US)

(21) Appl. No.: 19/208,228

(22) Filed: May 14, 2025

(51) Int. Cl. H02N 2/18; H10N 30/30; H10N 30/88

(52) U.S. Cl. CPC H02N 2/181; H02N 2/183; H10N 30/306; H10N 30/88

(57) ABSTRACT

A piezoelectric circuit, a piezoelectric device, and a piezoelectric generator are provided. The piezoelectric circuit includes an array of piezo elements arranged in parallel with one another, the array having a first terminal and a second terminal. The piezoelectric circuit includes a first energy storage circuit coupled to the array and configured to receive a first current flowing from the first terminal when the piezo elements are in a pressed status. The piezoelectric circuit includes a second energy storage circuit coupled to the array and configured to receive a second current flowing from the second terminal when the piezo elements are in a released status.

### TECHNICAL FIELD

Aspects of the present disclosure relate to a piezoelectric circuit, which may form part of a piezoelectric device and a piezoelectric generator.

### BACKGROUND

The piezoelectric effect describes a reaction that certain materials have under stress. Under mechanical stress, these materials create electricity that, if harvested, may provide power to electronic devices.

### BRIEF DESCRIPTION OF THE DRAWINGS

The described implementations and the advantages thereof may best be understood by reference to the following description taken in conjunction with the accompanying drawings. These drawings in no way limit any changes in form and detail that may be made to the described implementations without departing from the spirit and scope of the described implementations.

FIGS. 1A and 1B illustrate a piezo element from a top view and a side view, respectively, according to some implementations.

FIG. 2 illustrates a piezoelectric circuit, according to some implementations.

FIGS. 3A and 3B illustrate equivalent circuits of the piezoelectric circuit in FIG. 2 when the piezo elements are in a pressed status and a released status, respectively, according to some implementations.

FIGS. 4A and 4B illustrate side views of a piezoelectric device when piezo elements are in a released status and a pressed status, respectively, according to some implementations.

FIG. 4C illustrates a lid and a base of a piezoelectric device, according to some implementations.

FIG. 5A illustrates a side view of a piezoelectric generator, according to some implementations.

FIG. 5B illustrates the piezoelectric generator of FIG. 5A viewed along the A-A′ direction, according to some implementations.

### DETAILED DESCRIPTION

In general, piezoelectric effect happens when electric charges accumulate in certain solid materials in response to applied mechanical stress (e.g., pressure). Depending on the stress applied, a device made of piezoelectric materials may output currents having different magnitudes and in different directions. For example, when a piezoelectric element (or “piezo element”) made of crystal materials deforms due to the stress, the piezoelectric element may output a current in first direction. When the piezoelectric element recovers from the deformation due to the release of the stress or the application of a stress in the opposite direction, the piezoelectric element may output a current in a second direction opposite to the first direction. Multiple piezoelectric elements may be arranged in an array to amplify the currents generated.

The piezoelectric effect has been adopted in some applications. For example, there are device that use piezoelectric elements to capture sound energy and convert the captured energy to direct current (DC) electricity. With the drastic increase in the demand for household and industrial electricity, it is desirable to supplement existing power sources with energy provided by piezoelectric devices.

Implementations of this disclosure provide a piezoelectric circuit that may be used in piezoelectric devices and piezoelectric generators as a power source. The circuitry is relatively simple and yet efficient due to the ability to capture electricity both during the pressed state and the released state of a piezoelectric element. The piezoelectric generator has a structure with relatively low complexity, which makes the generator easy to manufacture and use.

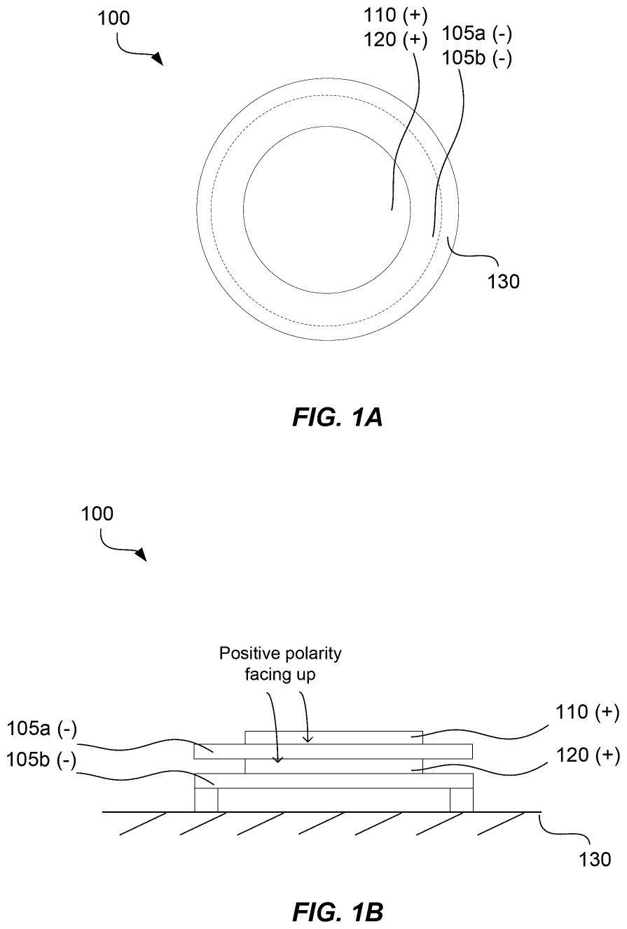

FIGS. 1A and 1B illustrate piezo element 100 from a top view and a side view, respectively, according to some implementations. In general, a piezo element may refer to a piece of electronic component made of piezoelectric material with the capability of generating electricity upon being pressed. In some implementations, piezo element 100 is a piezoelectric bimorph, which has a pair of piezo units.

As illustrated in FIGS. 1A and 1B, piezo element 100 has substrate 130 on which is arranged shims 105a and 105b (collectively shims 105), such as copper shims. Shims 105 and substrate 130 may be spaced apart by a gap to allow deformation of piezo material of piezo element 100 when pressed. In some implementations, substrate 130 has a circular shape, although this is not limiting.

Shims 105 are coupled to electrodes 110 and 120 respectively coated on two surfaces. Electrodes 110 and 120 serve as anodes of the piezo bimorphs while shims 105a and 105b serve as cathodes. Cathodes 105a and 105b may be connected to form the cathode of piezo element 100, while anodes 110 and 120 may connected to form the anode of piezo element 100. In some implementations, when piezo element 100 is pressed, e.g., receives a pressure on shims 105 towards substrate 130, piezo element 100 may generate a current that flows outbounds through the anode and inbounds through the cathode. Conversely, when the pressure on piezo element 100 is released, piezo element 100 may generate a current that flows outbounds through the anode and inbounds through the cathode. Apart from the bimorph structure illustrated in FIGS. 1A and 1B, other implementations may have piezo elements with different structures and connections.

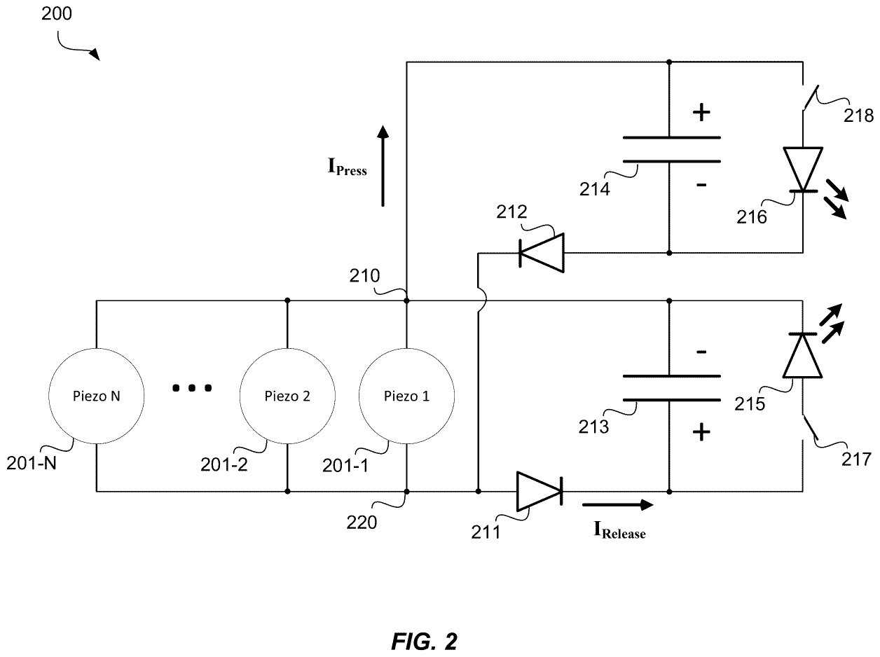

FIG. 2 illustrates piezoelectric circuit 200, according to some implementations. Piezoelectric circuit 200 includes an array of one or more piezo elements 201-1, 201-2, . . . 201-N, collectively referred to as piezo elements 201. Each of piezo elements 201 may be an instance of piezo element 100 of FIG. 1.

As illustrated, piezo elements 201 are arranged in parallel with one another between terminals 210 and 220. For example, each of piezo elements 201 may have a first electrode coupled to terminal 210 and have a second electrode coupled to terminal 220. Accordingly, when pressed, the array of piezo elements 201 operate as a power source to generate a current Iₚᵣₑₛₛ that flows outbounds through terminal 210 and inbounds through electrode 220. Conversely, when released, the array of piezo elements 201 operate as a power source to generate a current Iᵣₑₗₑₐₛₑ that flows outbounds through terminal 220 and inbounds through electrode 210.

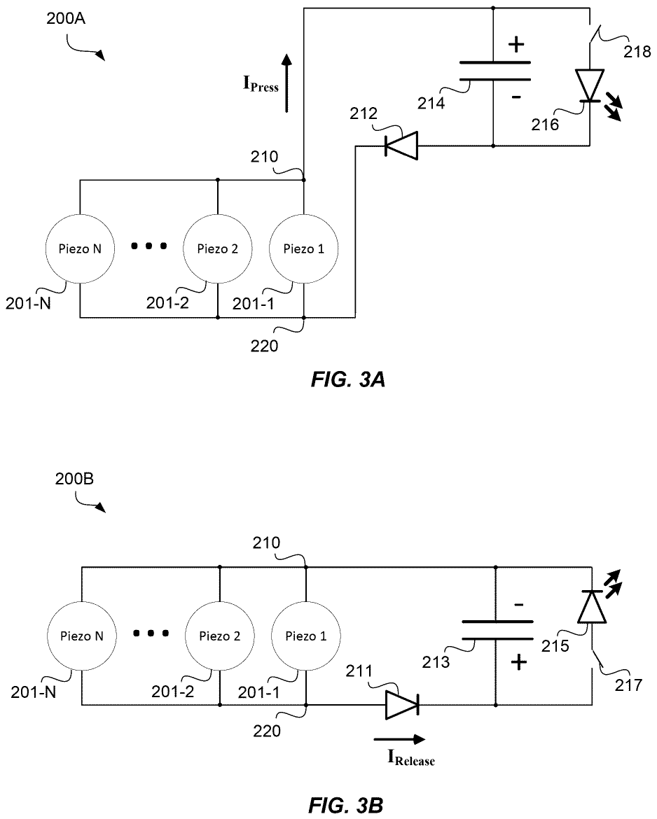

Piezoelectric circuit 200 further includes diodes 211, 212, 215, and 216, capacitors 213 and 214, and switches 217 and 218. Diodes 216 and 215 may be light emitting diodes (LEDs). When piezo elements 201 are pressed to generate Iₚᵣₑₛₛ, diode 211 blocks Iₚᵣₑₛₛ from flowing through, effectively disconnecting capacitor 213, diode 215, and switch 217 from piezo elements 201. The equivalent circuit in this situation is illustrated in FIG. 3A. Conversely, when piezo elements 201 are released to generate Iᵣₑₗₑₐₛₑ, diode 212 blocks Iᵣₑₗₑₐₛₑ from flowing through, effectively disconnecting capacitor 214, diode 216, and switch 218 from piezo elements 201. The equivalent circuit in this situation is illustrated in FIG. 3B.

FIGS. 3A and 3B illustrate equivalent circuits 200A and 200B of the piezoelectric circuit 200 in FIG. 2 when the array of piezo elements 201 is in a pressed status and a released status, respectively, according to some implementations.

As illustrated in FIG. 3A, when piezo elements 201 are pressed, current Iₚᵣₑₛₛ is in the forward direction of diodes 212 and 216. Accordingly, current Iₚᵣₑₛₛ flows through capacitor 214 to charge capacitor 214 when switch 218 is opened, and flows though LED 216 when switch 218 is closed. This way, by opening switch 218 and applying a pressure on piezo elements 201, a user can use piezo elements 201 to charge capacitor 214, which serves as an energy storage circuit. Also, by closing switch 218 and applying a pressure on piezo elements 201, a user can use LED 216 as an indicator of the pressed status of piezo elements 201.

As illustrated in FIG. 3B, when piezo elements 201 are released, current Iᵣₑₗₑₐₛₑ is in the forward direction of diodes 211 and 217. Accordingly, current Iᵣₑₗₑₐₛₑ flows through capacitor 213 to charge capacitor 213 when switch 217 is opened, and flows though LED 215 when switch 217 is closed. This way, by opening switch 217 and releasing the pressure on piezo elements 201, a user can use piezo elements 201 to charge capacitor 213, which serves as an energy storage circuit. Also, by closing switch 217 and releasing the pressure on piezo elements 201, a user can use LED 215 as an indicator of the released status of piezo elements 201.

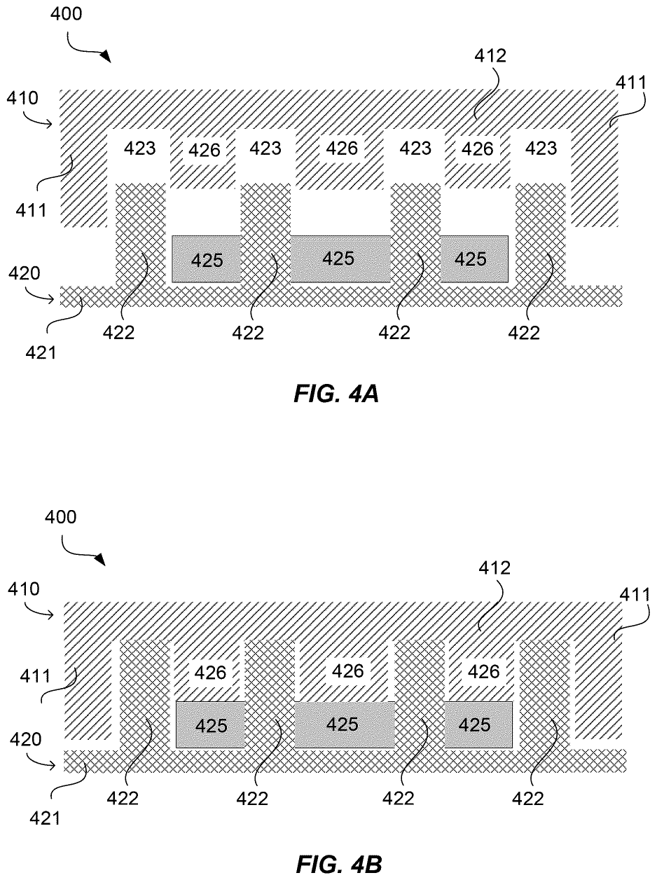

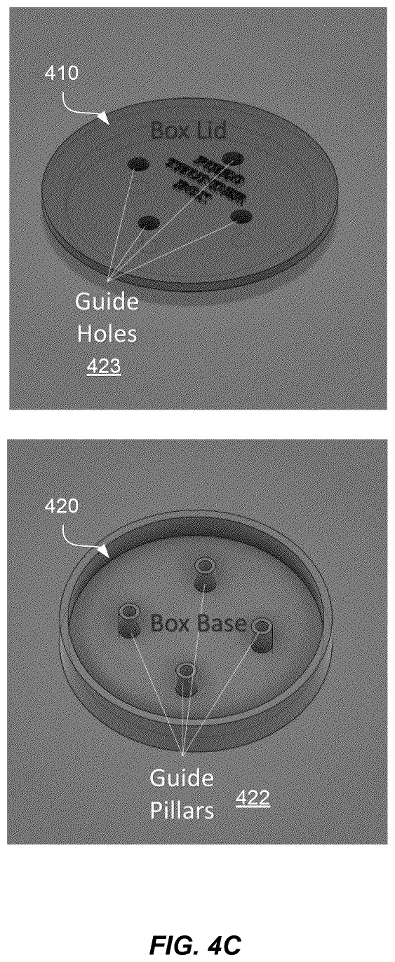

FIGS. 4A and 4B illustrate side views of a piezoelectric device 400, when piezo elements 425 are in a released status and a pressed status, respectively, according to some implementations. Piezo elements 425 may be arranged in an array and implemented in a piezoelectric circuit, such as piezoelectric circuit 200 of FIG. 2.

As illustrated in FIGS. 4A and 4B, piezoelectric device 400 includes base (or “box base”) 420 and lid (or “box lid”) 410 that at least partially covers base 420 from a vertical direction. Base 420 includes substrate 421, which may be a flat surface that extends in a horizontal direction. An array of one or more piezo elements 425 are arranged on substrate 421 and are separated by one or more pillars (or “guide pillars”) 422 of substrate 421.

Lid 410 has one or more edges 411 and one or more protrusions 426. Protrusions 426 extend in the vertical direction toward piezo elements 425, respectively. Protrusions 426 and edges 411 together define one or more holes 423 in which pillars 422 may be inserted.

Lid 410 is configured to move in the vertical direction towards and away from piezo elements 425 to switch piezo elements 425 between the pressed status and the released status. In FIG. 4A, when piezo elements 425 are in the released status, lid 410 is away from base 420 such that protrusions 426 do not apply a pressure on piezo elements 425. Conversely, in FIG. 4B, when piezo elements 425 are in the pressed status, lid 410 is close to base 420 such that protrusions 426 apply the pressure on piezo elements 425 and cause piezo elements 425 to deform. To protect piezo elements 425 from receiving excessive pressure and breaking down, the height of pillars 422 may be chosen to limit the maximum deformation of piezo elements 425.

FIG. 4C illustrates lid 410 and base 420 of piezoelectric device 400 of FIGS. 4A and 4B, according to some implementations. As illustrated, lid 410 and base 420 both have a circular shape, although this is not limiting. As also illustrated, guide pillars 422 each have a cylindrical wall encircling a hollow space. In some implementations, the hollow space may be used to guide wires that connect piezo elements 425 to other components of the piezoelectric circuit.

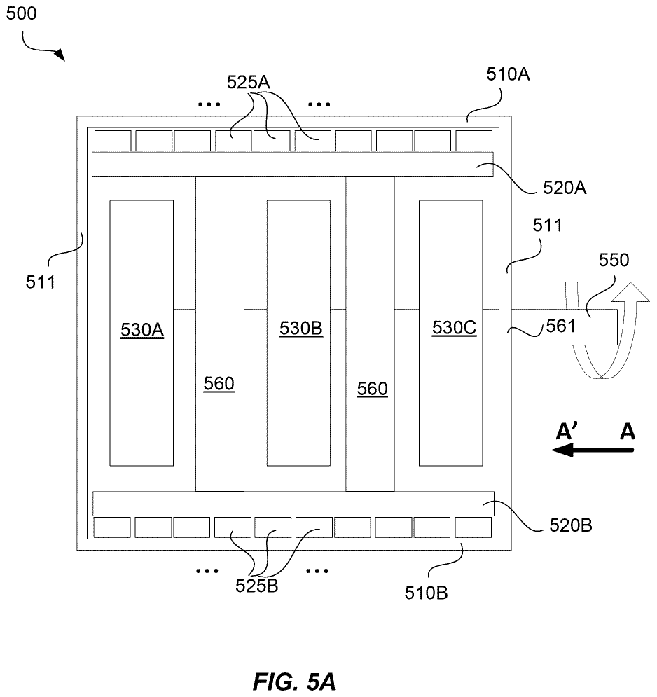

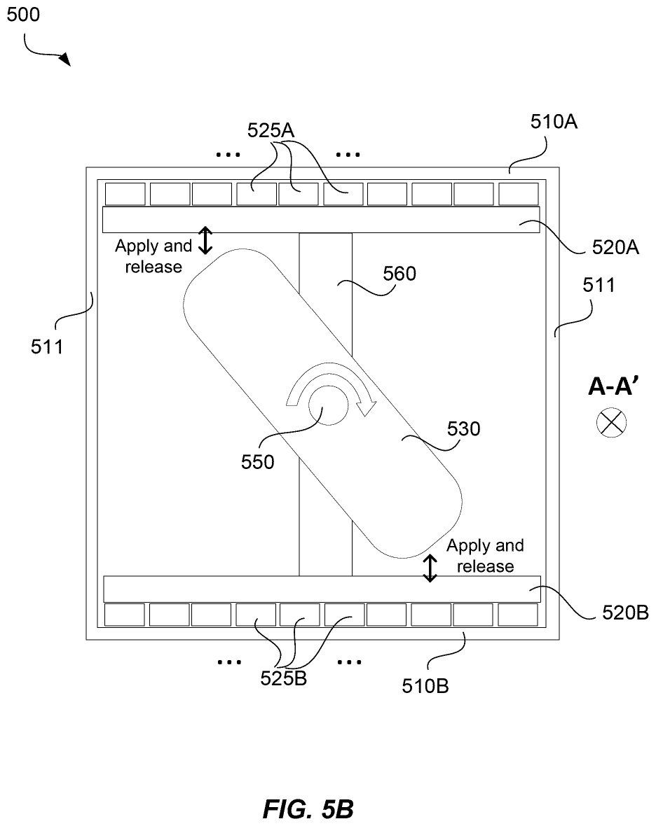

Piezoelectric device 400 may be used in a piezoelectric generator to provide electric power to electronic devices. Example implementations of the piezoelectric generator are described below with reference to FIGS. 5A and 5B.

FIG. 5A illustrates a side view of piezoelectric generator 500, and FIG. 5B illustrates piezoelectric generator 500 of FIG. 5A viewed along the A-A′ direction, according to some implementations.

As illustrated, piezoelectric generator 500 includes an enclosure formed by sidewalls 511. The enclosure may be made of, e.g., clear acrylic. The enclosure also includes ceiling 510A and floor 510B, which may be separated by one or more supports 560. Within the enclosure, a piezoelectric device is arranged on each of ceiling 510A and floor 510B. For example, piezoelectric generator 500 includes an array of piezo elements 525A arranged on an inner side of ceiling 510A and covered by lid 520A. Likewise, piezoelectric generator 500 includes an array of piezo elements 525B arranged on an inner side of floor 510B and covered by lid 520B. The inner sides of ceiling 510A and floor 510B may each define a piezoelectric surface, e.g., with wiring, electrodes, and other electronic components for a piezoelectric circuit. Thus, ceiling 510A serves as the substrate that, along with piezo elements 525A and lid 520A, forms an upper piezoelectric device. Likewise, floor 510B serves as the substrate that, along with piezo elements 525B and lid 520B, forms a lower piezoelectric device. Supports 560 may be hollow to guide wires from the upper piezoelectric device and the lower piezoelectric device to a common power outlet. In some implementations, the power outlet is located on ceiling 510A in the form of one or more holes (e.g., for anode and cathode) through ceiling 510A and the upper piezoelectric surface.

Although piezoelectric generator 500 is illustrated to have both an upper piezoelectric device and a lower piezoelectric device, some implementations may have only one piezoelectric device on, e.g., either of the ceiling or on the floor of the enclosure. Also, although piezoelectric generator 500 is illustrated to have both the ceiling and the floor of the enclosure, some implementations may have only one of the ceiling and the floor, which makes the enclosure partially open.

Piezoelectric generator 500 has shaft 550 that penetrates sidewalls 511 through one or more holes 561. Shaft 550 extends along axle A-A′, parallel to the piezoelectric surface(s) defined by ceiling 510A and/or floor 510B. Piezoelectric generator 500 also has one or more cams 530A, 530B, and 530C (collectively referred to as cams 530) attached to shaft 550. When shaft 550 rotates about axle A-A′, cams 530 also rotate about axle A-A′. In some implementations, shaft 550 has a handle at an end located outside the enclosure.

When cams 530 rotate, the height of an end of each cam varies. When an end of a cam reaches a lowest or highest point, the cam is in contact with a piezoelectric surface (e.g., lids 520A or 520B), applying a pressure on that piezoelectric surface to cause the corresponding piezo elements 525A or 525B to deform. After the end passes the lowest or highest point, the pressure is released. With the application and release of the pressure on the piezo elements 525A or 525B, piezoelectric generator 500 generates electrical power in the manner as described previously. The use of lids 520A and 520B makes it possible to apply and release pressures evenly on and from piezo elements 525A and/or 525B, thereby improving the robustness and durability of piezoelectric generator 500.

Accordingly, a user can mechanically, e.g., by hand, rotate shaft 550 to alternately apply and release pressures on the piezoelectric surface(s), thereby generating electric power in a simple and efficient manner. Piezoelectric generator 500 is thus useful in many scenarios, e.g., for charging household electronic devices in emergency situations when there is a power outage.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits. Reciting that a unit/circuit/component is “configured to” perform one or more tasks, or is “configurable to” perform one or more tasks, is expressly intended not to invoke 35 U.S.C. § 112, sixth paragraph, for that unit/circuit/component. Additionally, “configured to” or “configurable to” can include generic structure (e.g., generic circuitry) that is manipulated by software and/or firmware or mechanical or chemical processing tools to operate in manner that is capable of performing the task(s) at issue. “Configured to” may also include adapting a manufacturing process to fabricate devices (e.g., circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A piezoelectric circuit, comprising:
an array of piezo elements arranged in parallel with one another, the array having a first terminal and a second terminal;
a first energy storage circuit coupled to the array and configured to receive a first current flowing from the first terminal when the piezo elements are in a pressed status; and
a second energy storage circuit coupled to the array and configured to receive a second current flowing from the second terminal when the piezo elements are in a released status.

2. The piezoelectric circuit of claim 1,
wherein the first energy storage circuit comprises a first capacitor and a first diode arranged in series, the first diode configured to allow the first current to flow from the first terminal to the second terminal, and
wherein the second energy storage circuit comprises a second capacitor and a second diode arranged in series, the second diode configured to allow the second current to flow from the second terminal to the first terminal.

3. The piezoelectric circuit of claim 1, further comprising:
a first light-emitting diode (LED) circuit configured to receive the first current when the piezo elements are in the pressed status; and
a second LED circuit configured to receive the second current when the piezo elements are in the released status.

4. The piezoelectric circuit of claim 3, wherein the first LED circuit comprises a first LED and a first switch arranged in series, and wherein the second LED circuit comprises a second LED and a second switch arranged in series.

5. A piezoelectric device, comprising:
a piezoelectric circuit comprising an array of piezo elements, the array having a first terminal and a second terminal;
a base on which the array of piezo elements are arranged flat; and
a lid that covers the array of piezo elements,
wherein the piezoelectric circuit further comprises:
a first energy storage circuit coupled to the array and configured to receive a first current flowing from the first terminal when the piezo elements are in a pressed status; and
a second energy storage circuit coupled to the array and configured to receive a second current flowing from the second terminal when the piezo elements are in a released status.

6. The piezoelectric device of claim 5, wherein the lid is configured to move in a direction perpendicular to the array to switch the piezo elements from the pressed status and the released status.

7. The piezoelectric device of claim 6, wherein the lid comprises a plurality of protrusions separated by a plurality of holes, and wherein the base comprises a plurality of pillars respectively extending in the plurality of holes.

8. The piezoelectric device of claim 7, wherein the plurality of protrusions are configured to apply a pressure to the piezo elements when the piezo elements are in the pressed status.

9. The piezoelectric device of claim 5,
wherein the first energy storage circuit comprises a first capacitor and a first diode arranged in series, the first diode configured to allow the first current to flow from the first terminal to the second terminal, and
wherein the second energy storage circuit comprises a second capacitor and a second diode arranged in series, the second diode configured to allow the second current to flow from the second terminal to the first terminal.

10. The piezoelectric device of claim 5, wherein the piezoelectric circuit further comprises:
a first light-emitting diode (LED) circuit configured to receive the first current when the piezo elements are in the pressed status; and
a second LED circuit configured to receive the second current when the piezo elements are in the released status.

11. The piezoelectric device of claim 10, wherein the first LED circuit comprises a first LED and a first switch arranged in series, and wherein the second LED circuit comprises a second LED and a second switch arranged in series.

12. A piezoelectric generator, comprising:
a piezoelectric surface;
a piezoelectric device arranged on the piezoelectric surface;
a shaft extending along an axle parallel to the piezoelectric surface; and
a cam attached to the shaft and configured to rotate about the axle to be in contact with the piezoelectric surface,
wherein the piezoelectric device comprises a piezoelectric circuit comprising:
an array of piezo elements arranged in parallel with one another, the array having a first terminal and a second terminal;
a first energy storage circuit coupled to the array and configured to receive a first current flowing from the first terminal when the piezo elements are in a pressed status; and
a second energy storage circuit coupled to the array and configured to receive a second current flowing from the second terminal when the piezo elements are in a released status.

13. The piezoelectric generator of claim 12, further comprising an enclosure that encloses the piezoelectric device and the cam.

14. The piezoelectric generator of claim 13, wherein the enclosure comprises a sidewall having an opening, and wherein the shaft penetrates through the opening.

15. The piezoelectric generator of claim 13, wherein the piezoelectric surface is arranged on at least a floor or a ceiling of the enclosure.

16. The piezoelectric generator of claim 15, further comprising a support that separates the floor and the ceiling.

17. The piezoelectric generator of claim 12, wherein the cam applies a pressure on the piezo elements when in contact with the piezoelectric surface.

18. The piezoelectric generator of claim 12,
wherein the first energy storage circuit comprises a first capacitor and a first diode arranged in series, the first diode configured to allow the first current to flow from the first terminal to the second terminal, and
wherein the second energy storage circuit comprises a second capacitor and a second diode arranged in series, the second diode configured to allow the second current to flow from the second terminal to the first terminal.

19. The piezoelectric generator of claim 12, wherein the piezoelectric circuit further comprises:
a first light-emitting diode (LED) circuit configured to receive the first current when the piezo elements are in the pressed status; and
a second LED circuit configured to receive the second current when the piezo elements are in the released status.

20. The piezoelectric generator of claim 19, wherein the first LED circuit comprises a first LED and a first switch arranged in series, and wherein the second LED circuit comprises a second LED and a second switch arranged in series.
